(19) United States
(12) Patent Application Publication
(10) Pub. No.: US 2022/0339920 A1
(43) Pub. Date: Oct. 27, 2022

(54) POLYIMIDE COMPOSITE FILM FOR USE IN FLEXIBLE METAL CLAD SUBSTRATE

(71) Applicant: TAIMIDE TECHNOLOGY INCORPORATION, Hsinchu Hsien (TW)

(72) Inventors: JIA-HAO WU, Hsinchu Hsien (TW); TING-I LIU, Hsinchu Hsien (TW); MENG-YING TSAI, Hsinchu Hsien (TW)

(21) Appl. No.: 17/725,573

(22) Filed: Apr. 21, 2022

(30) Foreign Application Priority Data
Apr. 22, 2021 (TW) 110114530

(51) Int. Cl. B32B 27/28; B32B 27/08; B32B 27/32; B32B 15/08

(52) U.S. Cl. CPC B32B 27/281; B32B 27/08; B32B 27/322; B32B 15/08; B32B 2250/02; B32B 2250/03; B32B 2250/24; B32B 2327/12; B32B 2379/08; B32B 2307/732; B32B 2307/30; B32B 2307/20; B32B 2457/08

(57) ABSTRACT

A polyimide composite film for use in a flexible metal clad substrate, comprising: a polyimide base material film; a fluorine polymer layer, formed on at least one surface of the polyimide base material film, comprising polyimide resins and fluorine polymers, wherein the polyimide resin accounts for 2 to 20 wt % of the total solid content of the fluorine polymer layer, the aromatic functional group ratio of the polyimide resin in the fluorine polymer layer is greater than 35%, and the absorption onset wavelength (λonset) of the ultraviolet-visible spectrum is greater than 360 nm; a thickness ratio of the polyimide base material film to one layer of the fluorine polymer layers is 8:1 to 1:4; and a total thickness of the polyimide composite film is between 18 and 175 microns. Thus, the polyimide composite film has a low dielectric constant, low loss factor, and has good drilling processability.

### CROSS-REFERENCE TO RELATED APPLICATION

This non-provisional application claims priority under 35 U.S.C. § 119(a) on Patent Application No(s). 110114530 filed in Taiwan, R.O.C. on Apr. 22, 2021, the entire contents of which are hereby incorporated by reference.

### BACKGROUND OF THE INVENTION

### 1. Field of the Invention

The present disclosure relates to a polyimide composite film for use in a flexible metal clad substrate, and in particular to a polyimide composite film having a low dielectric constant, low loss factor, and having good drilling processability and reducing the occurrence of etching back in the process of flexible printed circuit boards.

### 2. Description of the Related Art

Flexible printed circuit boards have been widely used in various electronic products in daily life, such as mobile phones, tablet devices, notebook computers and other commodities. This kind of flexible printed circuit board and the covering base material thereof must consider the electricality, heat resistance, chemical resistance and dimensional stability of the material, so polyimide is usually used as a base material of the flexible printed circuit board and the covering layer.

In recent years, with the advent of 5G high-frequency transmission applications, high transmission frequency and high data transmission volume, signal loss may occur during transmission. In order to effectively reduce signal loss, reductions of the dielectric constant (Dk) and dissipation factor (Df) of the polyimide film are particularly important. The molecular structure design can be used to reduce the Dk and Df of the polyimide film, but the current limit of Dk is still higher than 3.0 and Df is higher than 0.004 at 10 GHz.

Among the various polymer materials, fluorine polymers are known to have lower Dk and Df materials, Dk<2.5 and Df<0.001 at 10 GHz, so related developers try to apply fluorine polymers to flexible metal clad substrate materials.

The implementing method can be roughly divided into three types:

Method 1, adding fluorine polymer particles to the polyimide film (patent document 1): the method uses the fluorine polymer particles to be mixed into the polyimide film in order to exert the characteristics of the low loss factor of the fluorine polymer. However, because of the need to maintain the overall property balance of the polyimide film, the ratio of fluorine polymers that can be added is limited, and the loss of line signals made after covering a metal foil cannot be effectively suppressed.

Method 2, covering a fluorine polymer film on the surface of polyimide (patent document 2): the method takes the polyimide film as a core layer, and laminates the fluorine polymer film on one or both sides thereof by a hot press, the film can be bonded with the metal foil at the same time. Because of the excellent dielectric properties of the fluorine polymer layer, the signal loss of the made line can be effectively reduced.

Method 3, as the multi-layer structure of Method 2, in addition to direct lamination with the fluorine polymer film, Method 3 uses meltable fluorine polymer particles to overlay on the polyimide film surface in a coating manner, and then they melt into a film through a processing temperature more than the melting point of the fluorine polymer (patent document 3).

Both of Method 2 and Method 3 which use of polyimide/fluorine polymer layered stacking can effectively reduce the loss factor. However, fluorine polymers reveals the pool absorption of 355 nm ultraviolet laser by drilling machines, it is not easy to drill holes, etching back leads to low yield and other shortcomings resulting in difficult processing and yield decline and other shortcomings.

### DOCUMENTS OF PRIOR ART

[Patent document 1] TW 1661004

[Patent document 2] TW 1461119

[Patent document 3] TW 201936377

### BRIEF SUMMARY OF THE INVENTION

A polyimide composite film for use in a flexible metal clad substrate comprises: a polyimide base material film; a fluorine polymer layer, which is formed on at least one surface of the polyimide base material film, comprising polyimide resins and fluorine polymers, wherein the polyimide resin accounts for 2 to 15 wt % of the total solid content of the fluorine polymer layer, the aromatic functional group ratio of the polyimide resin in the fluorine polymer layer is greater than 35%, and the absorption onset wavelength (λonset) of the ultraviolet-visible spectrum is greater than 360 nm; and a thickness ratio of the polyimide base material film to a total thickness of the fluorine polymer layer is 8:1 to 1:4, and a total thickness of the polyimide composite film is between 18 and 175 microns.

### BRIEF DESCRIPTION OF THE DRAWINGS

FIG. 1 is a schematic view of a polyimide composite film for use in a flexible metal clad substrate of the disclosure.

### DETAILED DESCRIPTION OF THE INVENTION

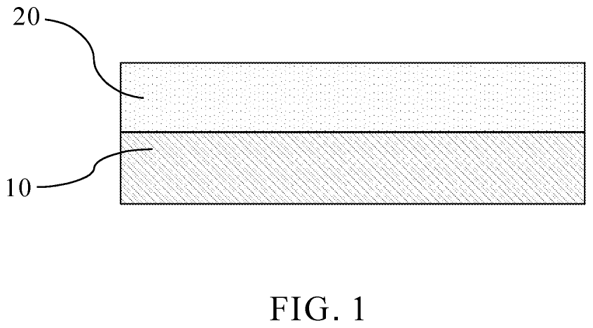

Referring to FIG. 1, the present disclosure is a polyimide composite film for use in a flexible metal clad substrate, comprising: a polyimide base material film 10; a fluorine polymer layer 20, which is formed on a surface of the polyimide base material film 10, comprising polyimides and fluorine polymers, wherein polyimide accounts for 2 to 20 wt % (2 to 15 wt % is preferred) of the total solid content of the fluorine polymer layer, the aromatic functional group ratio of polyimide in the fluorine polymer layer is greater than 35%, and the absorption onset wavelength (λonset) of the ultraviolet-visible spectrum is greater than 360 nm; among them, a thickness ratio of the polyimide base material film to a one layer of the fluorine polymer layer is 8:1 to 1:4 (a thickness ratio of the polyimide base material film to total thickness of the fluorine polymer layer is 8:1 to 1:4 is preferred), and a total thickness of the polyimide composite film is between 18 and 175 microns.

The aromatic functional group ratio of polyimide in the fluorine polymer layer is greater than 35%, and the absorption onset wavelength (λonset) of the ultraviolet-visible spectrum is greater than 360 nm; among them, a thickness ratio of the polyimide base material film to a total thickness of the fluorine polymer layer is 8:1 to 1:4, and a total thickness of the polyimide composite film is between 18 and 175 microns.

### Polyimide Base Material Film

The polyimide base material film selected for use in the present disclosure has no special limitations, in considering the dimensional stability, a base material film with a thermal expansion coefficient less than 20 ppm/° C., more preferably less than 15 ppm/° C. to maintain the overall dimensional stability of the polyimide composite film. Since the thermal expansion coefficient of the general fluorine polymer is greater than 100 ppm/° C., if the thermal expansion coefficient of the base material film is greater than 20 ppm/° C., the thermal expansion coefficient of the composite film will increase significantly after the base material film is cladded with the fluorine polymer layer.

In an embodiment of the polyimide composite film of the present disclosure, the fluorine polymer slurry may be coated on a polyimide film that has been dried and molded at high temperature, or may be coated on a semi-dried gel-like polyimide film, i.e., the polyimide base material film is allowed in the above state.

The composition of the polyimide base material film comprises one or more diamines and one or more dianhydride monomers are mixed and reacted, polymerized into a polyamic acid solution, and then coated into a film and baked.

Among them, diamine monomers may be: 4,4′-oxydianiline (4,4′-ODA), 3,4′-oxydianiline (3,4′-ODA), m-phenylenediamine (MPD), p-phenylenediamine (PPD), 2,2′-bis(trifluoromethyl)benzidine (TFMB), 4,4′-diaminodiphenyl-2,2-propane, 4,4′-diaminodiphenylmethane, 4,4′-diaminodiphenylamine, benzidine, 4,4′-diaminodiphenyl sulfide, 4,4′-diaminodiphenylsulfone, 3,3′-diaminodiphenylsulfone, 4,4′-diamino-2,2′-dimethyl-1,1′-biphenyl, 4,4′-diamino-3,3′-1,1′-dimethylbiphenyl, 1,5-diaminonaphthalene, 3,3′-dimethoxybenzidine, 1,4-bis-(p-aminophenoxy)-benzene, 1,3-bis-(p-aminophenoxy)-benzene, or any mixture thereof.

Among them, dianhydride monomers may be: pyromellitic dianhydride (PMDA), 2,3,6,7-naphthalenetetracarboxylic dianhydride, 3,3′,4,4′-biphenyltetracarboxylic dianhydride, 1,2,5,6-naphthalenetetracarboxylic dianhydride, 2,2′,3,3′-biphenyltetracarboxylic dianhydride, 2,2-bis-(3,4-dicarboxyphenyl)-propane dianhydride, bis-(3,4-dicarboxyphenyl)-sulfone dianhydride, bis-(3,4-dicarboxyphenyl)-phenyl)-ether dianhydride, 2,2-bis-(2,3-dicarboxyphenyl)-propane dianhydride, 1,1-bis-(2,3-dicarboxyphenyl)-ethane dianhydride, 1,1-bis-(3,4-dicarboxyphenyl)-ethane dianhydride, bis-(2,3-dicarboxyphenyl)-methane dianhydride, bis-(3,4-dicarboxyphenyl)-methane dianhydride, 3,4,3′,4′-benzophenone tetracarboxylic dianhydride, 4,4-(hexafluoroisopropylidene)diphthalic anhydride, or any mixture thereof.

The production method of high temperature drying for molding polyimide film is: mixing dehydrating agents such as acetic anhydride and catalysts such as triethylamine, pyridine, isoquinoline or methylpyridine in a polyamic acid solvent, and then the mixture is coated on a support, baked in a temperature range of 50° C. to 150° C. so that it is converted into a gel-like polyimide film, and after the gel-like polyimide film is removed from the support, a biaxial extension is performed, and put into an oven to be baked, a temperature of the high temperature oven is between 150° C. and 550° C., and the maximum temperature is preferably 350° C. to 550° C.

### Fluorine Polymer Layer

The fluorine polymer used in the present disclosure may be: a composition of one or more among polychlorotrifluoroethylene (PCTFE), fluorinated ethylene propylene copolymer (FEP), polyfluoroethylene (PVF), polyvinylidene difluoride (PVDF), ethylene chlorotrifluoroethylene copolymer (ECTFE), tetrafluoroethylene perfluoroether copolymer (PFA), ethylene tetrafluoroethylene copolymer (ETFE). The fluorine polymer is a particle state dispersed in an organic solvent, the median particle diameter (D50) is 1 to 20 microns, preferably 1 to 10 microns, the maximum particle diameter (Dmax) is 10 to 25 microns, preferably 10 to 20 microns. The reason is that if the particle size is too small, it is difficult to disperse, and if the particle size is too large, the film surface is uneven. The melting point of the fluorine polymer needs to be between 260° C. and 350° C., preferably between 280° C. and 310° C., so that the particles are baked, melted and sintered into a film of the fluorine polymer layer.

The fluorine polymer layer is made of coating and baking of the fluorine polymer dispersion, the fluorine polymer accounts for 70 to 98 wt % of the total fluorine polymer layer, and if the ratio of fluorine polymer is less than 80 wt %, the dielectric characteristics are poor. The composition of the fluorine polymer dispersion comprises: fluorine polymer particles account for 10 to 60 wt % of the total dispersion, preferably 30 to 50 wt %, to ensure that the linkage between the particles after drying is close; a dispersant accounts for 0.5 to 5 wt % of the total dispersion, preferably 0.5 to 3 wt %, if the amount of dispersant is too less, it cannot make the fluorine polymer particles disperse well; if the amount of dispersant is too much, it will affect the characteristics of the fluorine layer; the polyamic acid resin accounts for 1 to 7% of the total dispersion.

Because of lower film-formability of fluorine polymer particles and large thermal expansion coefficient of the fluorine polymer, the polyamic acid resin is added to reduce the thermal expansion coefficient of the fluorine polymer layer and enhance the film-formability. The addition method is to add a polyamic acid resin solution in the fluorine polymer slurry, the fluorine polymer slurry is coated on the polyimide film and baked, wherein the polyamic acid is reacted into polyimide. The ratio of polyamic acid added is 2 to 15 wt % of the total solid content of the fluorine polymer layer, when it is less than 2 wt %, it cannot achieve the effect of improving the physical properties, when it is higher than 15 wt %, the dielectric properties of the fluorine polymer layer become worse, for example, Df measured at a frequency of 10 GHz is higher than 0.0035, which cannot meet the characteristics of high-frequency applications.

The ratio of polyimide resin to fluorine polymer in the fluorine polymer layer may be obtained by the absorption signal ratio of 1363 cm⁻¹ and 1146 cm⁻¹ in the absorption spectrum of Attenuated Total Reflectance Fourier Transform Infrared spectroscopy (ATR-FTIR), of which 1363 cm⁻¹ is the signal of C—N stretching that polyamic acid is transformed into polyimide after tempering at high temperature, and 1146 cm⁻¹ is the signal of —CF2— stretching in the fluorine polymer. According to the experimental results, when the amount of polyamic acid is added at 2 to 15 wt %, a ratio of A_{1363 cm-1}/A_{1146 cm-1} is between 0.01 and 0.20.

In addition, the absorbance of fluorine polymers for the laser wavelength of 355 nanometer of ultraviolet (UV) laser drilling machines is too low, and they cannot be effectively cracked by lasers during the drilling process, which also leads to a high temperature so that the fluorine polymer layer melts at the drilling boundary and causes etching back. The depth of etching back (from the hole wall to the depth of the depression of the layer in the direction of the film surface) needs to be less than 10 microns, preferably less than 5 microns. When the depth of etching back is greater than 10 microns, it is easy to defect after plating copper or other metals.

The present disclosure adding polyimide resins to the fluorine polymer layer can also enhance the ultraviolet light absorbance of the fluorine polymer layer to improve drilling. The fluorine polymer layer is analyzed by ultraviolet-visible (UV-Vis) spectrometer, and the onset wavelength of the absorption spectrum of the layer (λonset, the intersection of the baseline and the tangent line of the rising section of the absorption peak) is greater than 360 nanometers, which ensures that the fluorine polymer layer has sufficient absorbance of 355 nanometer laser light. If the onset wavelength of the absorption spectrum is less than 360 nanometers, it fails to achieve good drilling results.

The composition of the added polyimide resin may be the same as that of the polyimide base material film, or it may be different. The composition of diamine or dianhydride monomer of the polyimide resin also requires to contain more than a certain ratio of aromatic structural functional groups, such as benzene rings or naphthalene rings, wherein the ratio of diamine and dianhydride aromatic functional groups of the constituents need to be greater than 35%.

$$Aromatic content ratio = \frac{( {C}_{1} \times {X}_{1} + {C}_{2} \times {X}_{2} + … + {C}_{n} \times {X}_{n} ) + ( {D}_{1} \times {Y}_{1} + {D}_{2} \times {Y}_{2} + … + {D}_{n} \times {Y}_{n} )}{( {A}_{1} \times {X}_{1} + {A}_{2} \times {X}_{2} + … + {A}_{n} \times {X}_{n} ) + ( {B}_{1} \times {Y}_{1} + {B}_{2} \times {Y}_{2} + … + {B}_{n} \times {Y}_{n} )}$$

A₁ to Aₙ in the equation are the molecular weights of the first to nth diamine monomers, respectively; B₁ to Bₙ are the molecular weights of the first to nth dianhydride monomers, respectively; C₁ to Cₙ are the molecular weights of the aromatic functional groups in the first to nth diamine monomers, respectively; and D₁ to Dₙ are the molecular weights of the aromatic functional groups in the first to nth dianhydride monomers, respectively; X₁ to Xₙ are the molar fractions added by the first to nth diamine monomers, respectively; Y₁ to Yₙ are the mole fractions added by the first to nth dianhydride monomers, respectively.

In the composition of the polyamic acid added to the fluorine polymer layer, diamine monomers may be: 4,4′-oxydianiline (4,4′-ODA), 3,4′-oxydianiline (3,4′-ODA), m-phenylenediamine (MPD), p-phenylenediamine (PPD), 2,2′-bis(trifluoromethyl)benzidine (TFMB), 4,4′-diaminodiphenyl-2,2-propane, 4,4′-diaminodiphenylmethane, 4,4′-diaminodiphenylamine, benzidine, 4,4′-diaminodiphenyl sulfide, 4,4′-diaminodiphenylsulfone, 3,3′-diaminodiphenylsulfone, 4,4′-diamino-2,2′-dimethyl-1,1′-biphenyl, 4,4′-diamino-3,3′-1,1′-dimethylbiphenyl, 1,5-diaminonaphthalene, 3,3′-dimethoxybenzidine, 1,4-bis-(p-aminophenoxy)-benzene, 1,3-bis-(p-aminophenoxy)-benzene, or any mixture thereof.

Among them, dianhydride monomers may be: pyromellitic dianhydride (PMDA), 2,3,6,7-naphthalenetetracarboxylic dianhydride, 3,3′,4,4′-biphenyltetracarboxylic dianhydride, 1,2,5,6-naphthalenetetracarboxylic dianhydride, 2,2′,3,3′-biphenyltetracarboxylic dianhydride, 2,2-bis-(3,4-dicarboxyphenyl)-propane dianhydride, bis-(3,4-dicarboxyphenyl)-sulfone dianhydride, bis-(3,4-dicarboxyphenyl)-phenyl)-ether dianhydride, 2,2-bis-(2,3-dicarboxyphenyl)-propane dianhydride, 1,1-bis-(2,3-dicarboxyphenyl)-ethane dianhydride, 1,1-bis-(3,4-dicarboxyphenyl)-ethane dianhydride, bis-(2,3-dicarboxyphenyl)-methane dianhydride, bis-(3,4-dicarboxyphenyl)-methane dianhydride, 3,4,3′,4′-benzophenone tetracarboxylic dianhydride, 4,4-(hexafluoroisopropylidene)diphthalic anhydride, or any mixture thereof.

The fluorine polymer particle dispersion is coated on a dried and molded polyimide film

The fluorine polymer particle dispersion may be coated on one or two sides of the polyimide base material film. The method of coating is not limited, and may use slot die method, micro gravure method, comma coating method and roll coating method. After the fluorine polymer dispersion is coated on the polyimide base material film, the polyimide base material film enters an oven with a high temperature section, at the same time support or extension in transverse direction (TD) can be carried out to avoid curling, the temperature of the high temperature oven is between 150 and 550° C., the maximum temperature is preferably 350 to 550° C., in order to ensure that the fluorine polymer particles are melted into a film.

The fluorine polymer dispersion may also be coated in a semi-dried gel-like polyimide base material film, the method is as follows: mixing dehydrating agents such as acetic anhydride and catalysts such as triethylamine, pyridine, isoquinoline or methylpyridine in a polyamic acid solution, and then the mixture is coated on a support, baked in a temperature range of 50° C. to 150° C. so that it is converted into a gel-like film. The difference is that the solvent content control of the gel-like polyimide film is adjusted by the baking temperature curve of the oven, and the baking temperature range is 50 to 150° C. The solvent content of the gel-like polyimide film is between 20 and 60 wt %, and if the solvent content is above 60 wt %, it causes film surface defects in the high temperature section, and if the solvent content is less than 20 wt %, it cannot have good affinity with fluorine polymer particles.

The polyimide composite film is pressed with a metal foil

A metal foil 30 of the present disclosure is made by means of the above-described polyimide composite film and metal foil using a heated metal roller or double belt hot press for continuous roll-to-roll pressing, or a vacuum plate hot press may also be used for sheet pressing. Among them, there is no special limit to the composition of metal foil, including copper, nickel, aluminum, gold and other metals or alloys, commonly using electrolytic copper foil or rolled copper foil, and the thickness of metal foil is not specially limited.

### Detection Method

ATR-FTIR spectroscopy uses FTIR spectrometer of model spectrum 100 manufactured by perkinelmer, Inc. combined with ATR modules.

Thermal expansion coefficient: measured by using TMA instrument of model Q400 manufactured by TA Instruments, Inc., taking the thermal expansion coefficient of 100 to 200° C.

Onset wavelength: measured by using UV-Visible Spectrometer of model V-630 manufactured by JASCO, Inc.

Aggregate phase size of polyimide resin: using Olympus BX51 metallographic optical microscope, the composite film is embedded in epoxy resin, and after grinding and polishing, it is measured at a magnification of 200 times.

Dielectric constant (Dk) and loss factor (Df): Agilent E5071C network analyzer combined with SPDR 10 GHz resonator, after the sample is baked at 120° C. for one hour, it is placed at 50% relative humidity, 25° C. room temperature for a day, and then it is measured.

Copper foil adhesion test: using universal tension machine of model lOST manufactured by Tinius Olsen, Inc., the test method is according to the standard test method of IPC-TM-650 2.4.

UV laser drilling: using ESI 5335xi drilling machine, the bore diameter is 100 μm. Test conditions: frequency of 40 KHz, laser energy set to 4 watts, the number of processing cycles set to 7 turns, processing speed set to 279 mm/sec.

### Polyamic Acid 1

20 Kg (100 mole %) of 4,4′-oxydianiline is dissolved in 167 Kg of dimethylacetamide (DMAc), and then about 21.8 Kg (100 mole %) of pyromellitic dianhydride is added and reacted to obtain about 20% polyamic acid 1 solution.

### Polyamic Acid 2

10 Kg (50 mole %) of 4,4′-oxydianiline and 5.4 Kg (50 mole %) of p-phenylenediamine are dissolved in 157 Kg of dimethylacetamide (DMAc), and then 10.9 Kg (50 mole %) of pyromellitic dianhydride and about 14.7 Kg (50 mole %) of 3,3′,4,4′-biphenyltetracarboxylic dianhydride are added and reacted to obtain about 20% polyamic acid 2 solution.

### Polyamic Acid 3

8.0 Kg (50 mole %) of 4,4′-diamino-2,2′-dimethyl-1,1′-biphenyl (m-Tolidine) and 12.075 Kg (50 mole %) of 2,2′-bis(trifluoromethyl)benzidine (TFMB) are dissolved in 162 Kg of dimethylacetamide (DMAc), and then 4.96 Kg (30 mole %) of pyromellitic dianhydride and about 15.53 Kg (70 mole %) of 3,3′,4,4′-biphenyltetracarboxylic dianhydride are added and reacted to obtain about 20% polyamic acid 3 solution.

### Polyamic Acid 4

2.134 Kg (100 mole %) of 2,2′-bis(trifluoromethyl)benzidine (TFMB) is dissolved in 17.17 Kg dimethylacetamide (DMAc), and then 1.48 Kg (50 mole %) of 4,4-(hexafluoroisopropylidene)diphthalic anhydride (6FDA) and about 1.047 Kg (50 mole %) of 1,2,3,4-cyclobutanetetracarboxylic dianhydride (CBDA) are added and reacted to obtain about 21% polyamic acid 4 solution.

### Example 1

### Preparation of Polyimide Base Material Films

10 Kg (50 mole %) of 4,4′-oxydianiline and 5.4 Kg (50 mole %) of p-phenylenediamine are dissolved in 157 Kg of dimethylacetamide (DMAc), and then 10.9 Kg (50 mole %) of pyromellitic dianhydride and about 14.7 Kg (50 mole %) of 3,3′,4,4′-biphenyltetracarboxylic dianhydride are added and reacted to obtain about 20% polyamic acid solution.

Acetic anhydride and methylpyridine are mixed in the polyamic acid, and then the mixture is coated on a support, baked in a temperature range of 50° C. to 150° C. so that it is converted into a gel-like film, and after the gel-like film is removed from the support, a biaxial extension is performed, and put into an oven to be baked, a temperature gradient of the high temperature oven is between 150° C. and 550° C., the preparation of the polyimide base material film having a thickness of 50 micron is completed.

### Preparation of Fluorine Polymer Dispersion

After mixing 24.4 Kg of dimethylacetamide solvent with 1.4 Kg dispersant (NEOS Ftergent710FL, solid content of 50 wt %), 20 Kg PFA powder (AGC EA-2000) is added to the above solution and stirred for one day, and then stirred with a homogenizer at 3000 rpm for two hours to be 45 wt % fluorine polymer dispersion. Then 4.21 Kg (solid content of 20 wt %) of polyamic acid 1 solution is added and mixed evenly for use, it is solid content of about 42% of fluorine polymer dispersion.

### Fluorine Polymer Dispersion Coating

The fluorine polymer dispersion is coated on both sides of the polyimide base material film, and it is supported with a needle plate to enter an 350° C. oven to be baked, to obtain a double-sided polyimide composite film cladded with fluorine polymer layer, the thickness is fluorine polymer layer/polyimide film/fluorine polymer layer=12.5 μm/50 μm/12.5 μm, it is a structure with the thickness ratio of F/PI/F about 1:4:1, and the polyimide composite film has a total thickness of 75 μm.

### Copper-Clad Substrate Making

Taking the above polyimide composite film with a size of 20 cm×30 cm, and it is pressed with a copper foil (Fukuda Metal CF-T49A-DS-HD2 12 μm, Rz: 1.1 μm) by using a vacuum plate heat press to obtain a double-sided copper clad substrate. The pressing conditions are that temperature rises from room temperature to 340° C. by 5° C. per minute, and keeps at a constant temperature of 340° C. for 10 minutes, pressure is 30 Kgf/cm², and the copper foil adhesion force test is carried out after completion.

### Example 2

Repeating the steps of Example 1, however, polyamic acid 2 solution is added to the fluorine polymer dispersion.

### Example 3

Repeating the steps of Example 1, however, polyamic acid 3 solution is added to the fluorine polymer dispersion.

### Example 4

Repeating the steps of Example 2, however, the weight ratio of the fluorine polymer to polyamic acid 2 in the fluorine polymer dispersion is 98/2.

### Example 5

Repeating the steps of Example 2, however, the weight ratio of the fluorine polymer to polyamic acid 2 in the fluorine polymer dispersion is 90/10.

### Example 6

Repeating the steps of Example 2, however, the weight ratio of the fluorine polymer to polyamic acid 2 in the fluorine polymer dispersion is 80/20 for subsequent production.

### Example 7

Repeating the steps of Example 2, however, the thicknesses of the fluorine polymer layers cladding the polyimide base material film on both sides are respectively 6 microns, it is a structure with the thickness ratio of F/PI/F about 1:8:1.

### Example 8

Repeating the steps of Example 2, however, the thicknesses of the fluorine polymer layers cladding the polyimide base material film on both sides are respectively 25 microns, it is a structure with the thickness ratio of F/PI/F about 1:2:1.

### Example 9

Repeating the steps of Example 2, however, the thickness of the polyimide base material film is 25 microns, it is a structure with the thickness ratio of F/PI/F about 1:2:1.

### Example 10

Repeating the steps of Example 2, however, the thickness of the polyimide base material film is 100 microns, the thickness of the fluorine polymer layer is 33 microns, it is a structure with the thickness ratio of F/PI/F about 1:3:1.

### Example 11

Repeating the steps of Example 2, however, the polyimide base material film is coated with a single-sided fluorine polymer layer, the total thickness is 75 um, it is a structure with the thickness ratio of F/PI as 1:2.

### Comparative Example 1

Repeating the steps of Example 1, however, there is no polyamic acid solution added to the fluorine polymer dispersion.

### Comparative Example 2

Repeating the steps of Example 2, however, the weight ratio of the fluorine polymer to polyamic acid 2 in the fluorine polymer dispersion is 70/30.

### Comparative Example 3

Repeating the steps of Example 2, however, polyamic acid 4 solution is added to the fluorine polymer dispersion for subsequent preparation.

Examples 1 to 3 are compared with comparative examples 1, 3. Based on the same base material film, the aromatic functional groups ratio of polyamic acid added to the fluorine polymer layer is greater than 25% and λonset is greater than 360 nm in Examples 1 to 3, and comparative example 1 fails to add polyamic acid, the aromatic functional groups ratio of polyamic acid in comparative example 3 is less than 25%, then λonset of comparative examples 1, 3 is less than 360 nm, resulting in serious etching back of drilling, the depth is greater than 10

Examples are compared with comparative example 1, since comparative example 1 fails to add polyamic acid to limit the thermal expansion of the fluorine polymer layer, the thermal expansion coefficient of Example 1 is greater than 20 ppm/° C., Examples that are added polyamic acid all have thermal expansion coefficient less than 20 ppm/° C.

Examples 2, 4 to 6 are compared with comparative examples 1 and 2. There is no polyamic acid added to the fluorine polymer layer of comparative example 1, so λonset<360 nm, the depth of etching back is greater than 10 μm; λonset of comparative example 2 is greater than 360 nm, but an excessive ratio of polyamic acid led to an increase in Dk/Df.

As to Examples 7 to 10, the thickness ratio of the base material film and the fluorine polymer layer can be adjusted to maintain the depth of etching back<10 um in the range of F/PI/F ratio as 1:8:1 to 1:2:1.

Those skilled in the art can understand various variations and modifications that could be made to the disclosure without departing from the scope and spirit of the present disclosure set forth in the claims fall into a part of the disclosure.

The polyamic acid for the production of polyimide base material is as follows:

| | diamines | | | | | | | | aromatic |
|---|---|---|---|---|---|---|---|---|---|
| | | m- | 4,4′- | p- | dianhydrides | | | | functional |
| | TFMB | Tolidine | ODA | PDA | PMDA | BPDA | 6FDA | CBDA | group ratio |
| polyamic | — | — | 100 | — | 100 | — | — | — | 54.70% |
| acid 1 | | | | | | | | | |
| polyamic | — | — | 50 | 50 | 50 | 50 | — | — | 55.37% |
| acid 2 | | | | | | | | | |
| polyamic | 50 | 50 | — | — | 30 | 70 | — | — | 51.86% |
| acid 3 | | | | | | | | | |
| polyamic | 100 | — | — | — | — | — | 50 | 50 | 32.33% |
| acid 4 | | | | | | | | | |

Table of Examples and comparative examples (E. 1 to E. 11 respectively represent Example 1 to Example 11 and CE. 1 to CE. 3 respectively represent comparative example 1 to comparative example 3 in the following Table)

| | | fluorine polymer layer | | | | | | | | | | | | | | |
|---|---|---|---|---|---|---|---|---|---|---|---|---|---|---|---|---|
| | | | | | Ratio | | | | | | | | | | | |
| | poly- | | | | of | | | | | | | | | | | Copper |
| | imide | | Ratio | | poly- | | | | | | | | | | | clad |
| | base | | of | | amic | | | | | | polyimide | | | | | plate |
| | material | Ratio | poly- | Kind | acid | | A₁₃₆₃ | | | | composite film | | | | | Depth |
| | film | of | amic | of | aromatic | | cm⁻¹/ | | Dk | Df | | Single | | Dk | Df | of |
| | Thick- | fluorine | acid | poly- | func- | Thick- | A₁₁₄₆ | | RH50%, | | Thick- | side/ | CTE | RH50%, | | etching |
| | ness | polymer | resin | amic | tional | ness | cm⁻¹ | λₒₙₛₑₜ | 25° C., | | ness | double | ppm/ | 25° C., | | back |
| | μm | wt % | wt % | acid | groups | μm | — | nm | one day | | μm | side | ° C. | one day | | μm |
| E. 1 | 50 | 95 | 5 | polyamic | 54.70% | 12.5 | 0.025 | 443 | 2.04 | 0.0025 | 75 | double | 16 | 2.91 | 0.0038 | 5 |
| | | | | acid 1 | | | | | | | | side | | | | |
| E. 2 | 50 | 95 | 5 | polyamic | 55.37% | 12.5 | 0.027 | 421 | 2.03 | 0.0017 | 75 | double | 15 | 2.86 | 0.0036 | 6 |
| | | | | acid 2 | | | | | | | | side | | | | |
| E. 3 | 50 | 95 | 5 | polyamic | 51.86% | 12.5 | 0.023 | 413 | 2.03 | 0.0018 | 75 | double | 15 | 2.81 | 0.0035 | 5 |
| | | | | acid 3 | | | | | | | | side | | | | |
| E. 4 | 50 | 98 | 2 | polyamic | 55.37% | 12.5 | 0.014 | 404 | 2.01 | 0.0016 | 75 | double | 16 | 2.84 | 0.0033 | 8 |
| | | | | acid 2 | | | | | | | | side | | | | |
| E. 5 | 50 | 90 | 10 | polyamic | 55.37% | 12.5 | 0.043 | 451 | 2.13 | 0.0022 | 75 | double | 15 | 2.88 | 0.0037 | 4 |
| | | | | acid 2 | | | | | | | | side | | | | |
| E. 6 | 50 | 80 | 20 | polyamic | 55.37% | 12.5 | 0.078 | 465 | 2.27 | 0.0030 | 75 | double | 14 | 2.89 | 0.0045 | 3 |
| | | | | acid 2 | | | | | | | | side | | | | |
| E. 7 | 50 | 95 | 5 | polyamic | 51.86% | 6 | 0.023 | 413 | 2.03 | 0.0018 | 62 | double | 12 | 2.98 | 0.0041 | 4 |
| | | | | acid 3 | | | | | | | | side | | | | |
| E. 8 | 50 | 95 | 5 | polyamic | 51.86% | 25 | 0.023 | 413 | 2.03 | 0.0018 | 100 | double | 18 | 2.86 | 0.0033 | 6 |
| | | | | acid 3 | | | | | | | | side | | | | |
| E. 9 | 25 | 95 | 5 | polyamic | 51.86% | 12.5 | 0.023 | 413 | 2.03 | 0.0018 | 50 | double | 18 | 2.86 | 0.0034 | 4 |
| | | | | acid 3 | | | | | | | | side | | | | |
| E. 10 | 100 | 95 | 5 | polyamic | 51.86% | 33 | 0.023 | 413 | 2.03 | 0.0018 | 175 | double | 14 | 2.87 | 0.0035 | 7 |
| | | | | acid 3 | | | | | | | | side | | | | |
| E. 11 | 50 | 95 | 5 | polyamic | 55.37% | 25 | 0.027 | 421 | 2.03 | 0.0017 | 75 | single | 15 | 2.87 | 0.0037 | 6 |
| | | | | acid 2 | | | | | | | | side | | | | |
| CE. 1 | 50 | 100 | 0 | — | — | 12.5 | 0.005 | 240 | 2.03 | 0.0015 | 75 | double | 22 | 2.84 | 0.0031 | 18 |
| | | | | | | | | | | | | side | | | | |
| CE. 2 | 50 | 70 | 30 | polyamic | 55.37% | 12.5 | 0.115 | 430 | 2.41 | 0.0037 | 75 | double | 14 | 3.05 | 0.0051 | 7 |
| | | | | acid 2 | | | | | | | | side | | | | |
| CE. 3 | 50 | 95 | 5 | polyamic | 23.45% | 12.5 | 0.022 | 321 | 2.07 | 0.0016 | 75 | double | 18 | 2.85 | 0.0034 | 13 |
| | | | | acid 4 | | | | | | | | side | | | | |

What is claimed is:

1. A polyimide composite film for use in a flexible metal clad substrate, comprising:
a polyimide base material film;
a fluorine polymer layer, formed on at least one surface of the polyimide base material film, comprising polyimide resins and fluorine polymers, wherein the polyimide resin accounts for 2 to 20 wt % of the total solid content of the fluorine polymer layer, the aromatic functional group ratio of the polyimide resin in the fluorine polymer layer is greater than 35%, and the absorption onset wavelength (2. onset) of the ultraviolet-visible spectrum is greater than 360 nm;
a thickness ratio of the polyimide base material film to one layer of the fluorine polymer layers is 8:1 to 1:4; and a total thickness of the polyimide composite film is between 18 and 175 microns.

2. The polyimide composite film for use in a flexible metal clad substrate according to claim 1, wherein the polyimide composite film has a thermal expansion coefficient less than 20 ppm/° C.

3. The polyimide composite film for use in a flexible metal clad substrate according to claim 1, wherein a ratio of A_{1363 cm-1}/A_{1146 cm-1} of ATR-FTIR absorption spectrum of the fluorine polymer layer is between 0.01 and 0.08.

4. The polyimide composite film for use in a flexible metal clad substrate according to claim 1, wherein in the composition of the polyamic acid resin contained in the fluorine polymer layer, diamine monomers are: 4,4′-oxydianiline (4,4′-ODA), 3,4′-oxydianiline (3,4′-ODA), m-phenylenediamine (MPD), p-phenylenediamine (PPD), 2,2′-bis(trifluoromethyl)benzidine (TFMB), 4,4′-diaminodiphenyl-2,2-propane, 4,4′-diaminodiphenylmethane, 4,4′-diaminodiphenylamine, benzidine, 4,4′-diaminodiphenyl sulfide, 4,4′-diaminodiphenylsulfone, 3,3′-diaminodiphenylsulfone, 4,4′-diamino-2,2′-dimethyl-1,1′-biphenyl, 4,4′-diamino-3,3′-1,1′-dimethylbiphenyl, 1,5-diaminonaphthalene, 3,3′-dimethoxybenzidine, 1,4-bis-(p-aminophenoxy)-benzene, 1,3-bis-(p-aminophenoxy)-benzene, or any mixture thereof; wherein dianhydride monomers are: pyromellitic dianhydride (PMDA), 2,3,6,7-naphthalenetetracarboxylic dianhydride, 3,3′,4,4′-biphenyltetracarboxylic dianhydride, 1,2,5,6-naphthalenetetracarboxylic dianhydride, 2,2′,3,3′-biphenyltetracarboxylic dianhydride, 2,2-bis-(3,4-dicarboxyphenyl)-propane dianhydride, bis-(3,4-dicarboxyphenyl)-sulfone dianhydride, bis-(3,4-dicarboxyphenyl)-phenyl)-ether dianhydride, 2,2-bis-(2,3-dicarboxyphenyl)-propane dianhydride, 1,1-bis-(2,3-dicarboxyphenyl)-ethane dianhydride, 1,1-bis-(3,4-dicarboxyphenyl)-ethane dianhydride, bis-(2,3-dicarboxyphenyl)-methane dianhydride, bis-(3,4-dicarboxyphenyl)-methane dianhydride, 3,4,3′,4′-benzophenone tetracarboxylic dianhydride, 4,4-(hexafluoroisopropylidene)diphthalic anhydride, or any mixture thereof.

5. The polyimide composite film for use in a flexible metal clad substrate according to claim 1, wherein the fluorine polymer layer is formed on two surfaces of the polyimide composite film.
